(19) United States
(12) Patent Application Publication
(10) Pub. No.: US 2003/0008466 A1
(43) Pub. Date: Jan. 9, 2003

(54) Semiconductor device and method of fabricating the same

(75) Inventor: Toshihiro Inada, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/136,399

(22) Filed: May 2, 2002

(30) Foreign Application Priority Data
Jul. 9, 2001 (JP) 2001-207293(P)

(51) Int. Cl. H01L 21/331

(52) U.S. Cl. 438/369

(57) ABSTRACT

In order to provide a method of fabricating a semiconductor device improved to be capable of attaining a high refresh property, a gate electrode is formed on a semiconductor substrate through a gate oxide film. Impurity ions for forming source/drains on both sides of the gate electrode are implanted into the surface of the semiconductor substrate. Inert ions are implanted into the surface of the semiconductor substrate. The semiconductor substrate is heat-treated in a nitrogen atmosphere, for forming an SiN layer on the surface of the gate electrode. The semiconductor substrate is heat-treated in an oxidizing atmosphere, for forming an additional oxide film.

### BACKGROUND OF THE INVENTION

1. Field of the Invention

The present invention generally relates to a method of fabricating a semiconductor device, and more specifically, it relates to a method of fabricating a semiconductor device improved to be capable of attaining a high refresh property. The present invention also relates to a semiconductor device obtained by such a method.

2. Description of the Prior Art

FIGS. 11 to 16 are sectional views of a semiconductor device for illustrating a conventional method of fabricating a dynamic random access memory (DRAM).

Referring to FIG. 11, isolation oxide films 2 are formed in the main surface of a semiconductor substrate 1.

Referring to FIG. 12, ions for forming a well 3 and ions for controlling the threshold voltage (Vth) of a transistor are implanted.

Referring to FIG. 13, gate electrodes 4 and source/drain regions 5 are formed, followed by formation of side wall films 21.

Referring to FIG. 14, an interlayer isolation film 6 is formed to cover the gate electrodes 4, and a contact hole is formed in the interlayer isolation film 6 for forming a bit line 7.

Referring to FIG. 15, another interlayer isolation film 8 is formed to cover the bit line 7, for thereafter forming cell capacitors consisting of lower electrodes 9, capacitance isolation films 10 and upper electrodes 11.

Referring to FIG. 16, an interlayer isolation film 12 is formed to cover the cell capacitors, and metal wires 13 are formed on the interlayer isolation film 12. A passivation film 14 is formed on the interlayer isolation film 12 to cover the metal wires 13.

In the DRAM formed in the aforementioned manner, improvement of the refresh property is an extremely important item. This refresh property includes a pause refresh property related to characteristics in a data holding period in a positive device state and a disturb refresh property related to data holding ability in a dynamic state around a noted bit.

In such a conventional DRAM, drain leakage in a transfer gate supposedly resulting from gate induced drain leakage (GIDL) is observed. Such drain leakage is caused by band-to-band or band-trap-band tunneling resulting from band bending induced by a drain-to-gate electric field, to reduce charge holding ability, i.e., data holding ability.

Such GIDL may be suppressed by increasing the thickness of an oxide film located under side walls, increasing the thickness of an SiO₂ film on a drain edge of the transfer gate or removing a projection or a corner of an edge thereby relaxing the electric field.

FIGS. 17 to 19 illustrate a conventional method of increasing the thickness of an SiO₂ film.

Referring to FIG. 17, a gate oxide film 15 is formed on a silicon substrate 1. A gate electrode 4 is formed on the gate oxide film 15.

Referring to FIG. 18, the gate electrode 4 is employed as a mask for implanting impurity ions (P) for forming source/drain regions.

Referring to FIG. 19, heat treatment is performed in an oxidizing atmosphere, for forming an additional oxide film 16. The implanted P ions diffuse due to this heat treatment, for forming source/drain diffusion regions 5.

In the conventional method, however, the additional oxide film 16 is formed only by heat treatment in an O₂ atmosphere as described above, and hence the heat treatment must be performed over a long time in order to attain a desired thickness of the oxide film. Consequently, the impurity ions diffuse into the semiconductor substrate 1, to disadvantageously reduce a short margin of transistor characteristics.

### SUMMARY OF THE INVENTION

The present invention has been proposed in order to solve the aforementioned problem, and an object thereof is to provide a method of fabricating a semiconductor device improved to be capable of attaining a high pause refresh property in a DRAM in particular.

Another object of the present invention is to provide a method of fabricating a semiconductor device improved for attaining a high pause refresh property without reducing a short margin of transistor characteristics.

Still another object of the present invention is to provide a semiconductor device fabricated by such a method.

In the method of fabricating a semiconductor device according to the present invention, a gate electrode is first formed on a semiconductor substrate through a gate oxide film (first step). Impurity ions for forming source/drain regions on both sides of the aforementioned gate electrode are implanted into the surface of the aforementioned semiconductor substrate (second step). Inert ions are implanted into the surface of the aforementioned semiconductor substrate (third step). The aforementioned semiconductor substrate is heat-treated in a nitrogen atmosphere, for forming an SiN layer on the surface of the aforementioned gate electrode (fourth step). The aforementioned semiconductor substrate is heat-treated in an oxidizing atmosphere (fifth step).

According to a preferred mode of the present invention, the aforementioned inert ions contain Ar.

According to another preferred mode of the present invention, the aforementioned inert ions are perpendicularly implanted into the surface of the aforementioned semiconductor substrate.

Alternatively, the inert ions may be obliquely implanted into the surface of the aforementioned semiconductor substrate.

According to still another preferred mode of the present invention, the heat treatment is performed in the aforementioned fourth step by performing lamp annealing at a temperature of 900° C. to 1100° C.

The method according to the present invention is applied to fabrication of a dynamic random access memory.

A semiconductor device according to another aspect of the present invention comprises a semiconductor substrate. An oxide film is formed on the aforementioned semiconductor substrate. A gate electrode is formed on the aforementioned oxide film. First lower surfaces of the aforementioned oxide film positioned on both sides of the aforementioned gate electrode are located downward beyond a second lower surface of the aforementioned oxide film positioned immediately under the gate electrode. The aforementioned first lower surfaces and the aforementioned second lower surface are connected with each other through step surfaces substantially perpendicularly extending downward from ends of the aforementioned first lower surfaces.

According to a preferred mode of the present invention, the surface of the aforementioned gate electrode is covered with an SiN layer.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 5 are sectional views of a semiconductor device showing first to fifth steps in a method of fabricating a semiconductor device according to a first embodiment of the present invention;

FIGS. 6 to 10 are sectional views of a semiconductor device showing first to fifth steps in a method of fabricating a semiconductor device according to a second embodiment of the present invention;

FIGS. 11 to 16 are sectional views of a semiconductor device showing first to sixth steps in a conventional method of fabricating a DRAM; and

FIGS. 17 to 19 are sectional views of a semiconductor device showing first to third steps in a conventional method of fabricating a transistor.

### DESCRIPTION OF THE PREFERRED EMBODIMENTS

Embodiments of the present invention are now described with reference to the drawings.

First Embodiment

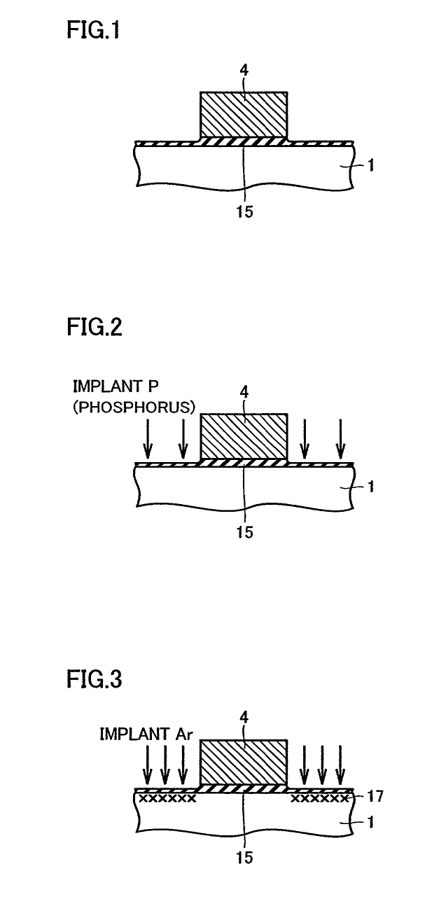

Referring to FIG. 1, a gate oxide film 15 and a gate electrode 4 are formed on a silicon substrate 1.

Referring to FIG. 2, the gate electrode 4 is employed as a mask for ion-implanting phosphorus (P) for forming source/drain regions into the main surface of the silicon substrate 1.

Referring to FIG. 3, inert ions (Ar) are implanted into the main surface of the silicon substrate 1 for forming damage layers 17 on the surface of the silicon substrate 1. The Ar ions are implanted under conditions of 20 KeV, 2×10¹⁵/cm² at an angle of 0°.

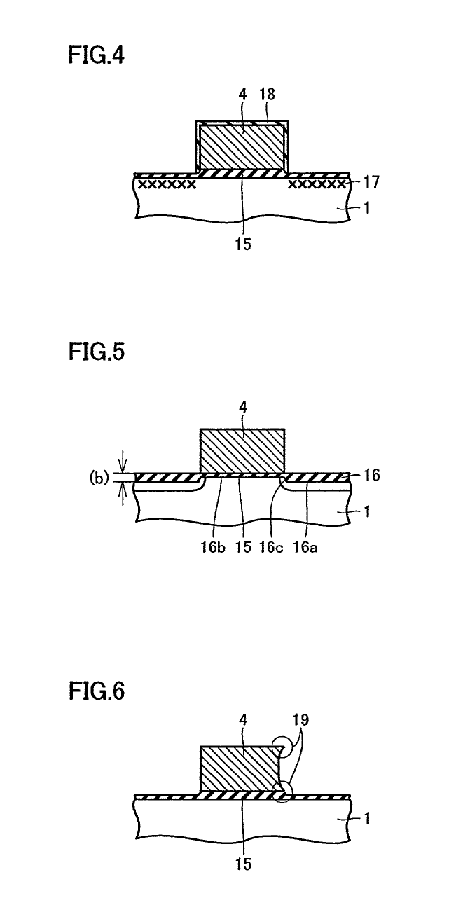

Referring to FIG. 4, the silicon substrate 1 is heat-treated in a nitrogen atmosphere after the ion implantation, for forming an extremely thin SiN layer 18 on the surface of the gate electrode 4.

The reason for forming the SiN layer 18 is now described.

The gate electrode 4, also employed as a word line, must have low resistance. When the gate electrode 4 generally made of silicide having a high melting point is directly exposed to the oxidizing atmosphere, an uncontrollable oxide film is disadvantageously formed on the surface thereof. Transistor characteristics cannot be controlled if such an oxide film is formed on the gate electrode 4, and hence the surface of the gate electrode 4 must not be directly exposed to the oxidizing atmosphere. Therefore, the heat treatment is performed in the N₂ atmosphere for forming the extremely thin SiN layer 18 on the surface of the gate electrode 4, thereby preventing the gate electrode 4 from abnormal oxidation.

The heat treatment in the N₂ atmosphere is carried out by performing lamp annealing at a temperature of 900° C. to 1100° C.

Referring to FIG. 5, heat treatment is carried out in an oxidizing atmosphere. This heat treatment is carried out in a lamp annealing apparatus under conditions of an O₂ atmosphere, 1000° C. and one minute.

According to this embodiment, an additional oxide film 16 having a desired thickness can be obtained through short-time heat treatment by forming the damage layers 17 on the surface of the substrate 1 and increasing the oxidation rate on the damage layers 17. Assuming that (a) represents the thickness of the additional oxide film 16 shown in FIG. 19 and (b) represents that of the additional oxide film 16 shown in FIG. 5, (a)<(b).

The structure of the additional oxide film 16 obtained in this embodiment is now described. First lower surfaces 16a of the additional oxide film 16 positioned on both sides of the gate electrode 4 are located downward beyond a second lower surface 16b of the additional oxide film 16 positioned immediately under the gate electrode 4. The first lower surfaces 16a and the second lower surface 16b are connected with each other through step surfaces 16c substantially perpendicularly extending downward from ends of the first lower surfaces 16a. According to this method, the additional oxide film 16 can be formed by short-time heat treatment, whereby impurities contained in the substrate 1 do not diffuse and a short margin of transistor characteristics is not reduced.

Further, the thickness of an SiO₂ film can be increased on a drain edge of a transfer gate, whereby no drain leakage is caused in the transfer gate but the pause refresh property can be improved.

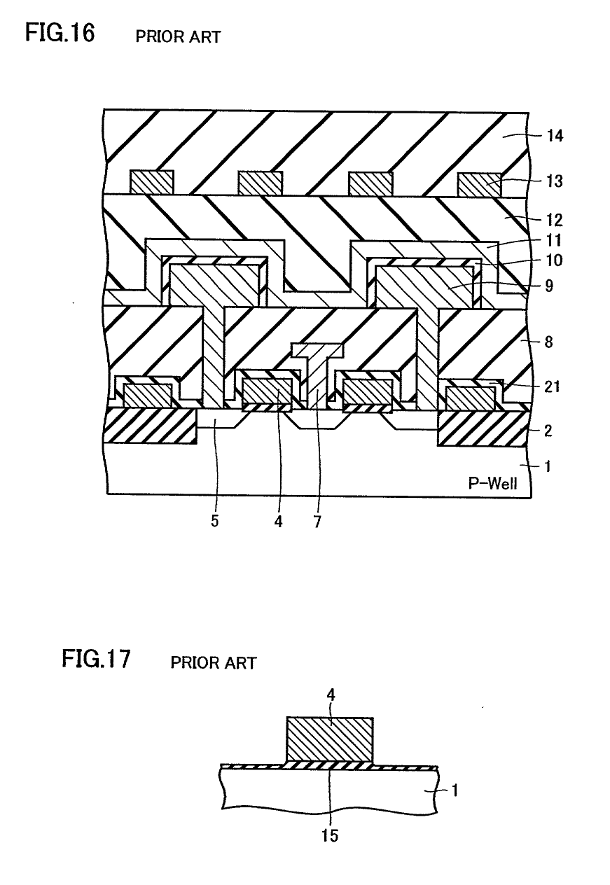

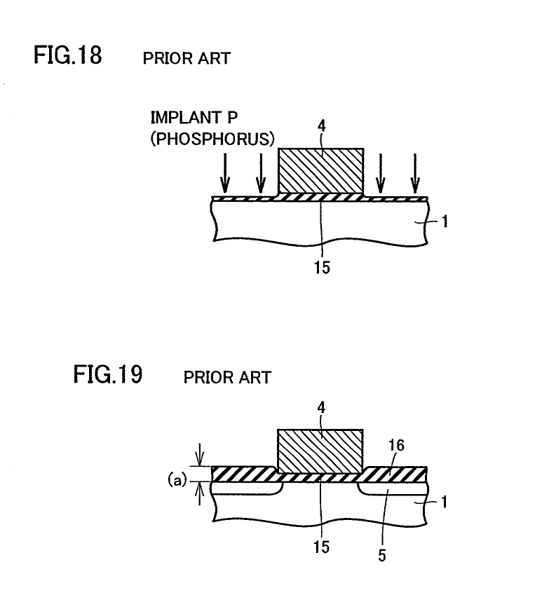

After the heat treatment, side wall films are formed by CVD and thereafter steps similar to those of the prior art shown in FIGS. 14 to 16 are carried out for completing a DRAM according to this embodiment.

While the inert ions are implanted after the ion implantation for forming the source/drain regions in the aforementioned embodiment, the order of ion implantation may alternatively be reversed.

Second Embodiment

While the inert ions are perpendicularly implanted into the silicon substrate 1 in the first embodiment, the present invention is not restricted to this.

A second embodiment of the present invention is applicable also when a gate electrode 4 causes shape abnormality.

Referring to FIG. 6, shape abnormality 19 may be caused when the gate electrode 4 is formed on a silicon substrate 1 through a gate oxide film 15.

The gate electrode 4 has a two-layer structure formed by a polysilicon layer and a high melting point silicide layer. The polysilicon layer, which is polycrystalline as a matter of course, has grain boundaries. In general etching, therefore, the polysilicon layer exhibits fine irregularity at the level of a scanning electron microscope (SEM) due to the grain boundaries. This results in the shape abnormality 19.

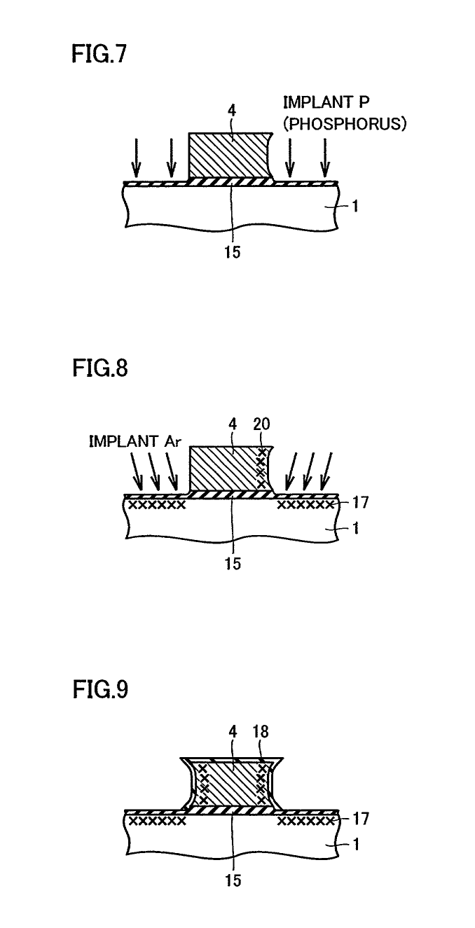

Referring to FIG. 7, the gate electrode 4 is employed as a mask for ion-implanting phosphorus (P) for forming source/drain regions into the surface of the silicon substrate 1.

Referring to FIG. 8, inert ions are rotationally implanted at an angle. For example, Ar is rotationally ion-implanted at an angle of 7°. The concentration of Ar is set to 2×10¹⁵/cm².

Damage layers 17 are formed in the surface of the silicon substrate 1 due to the aforementioned Ar ion implantation, while a damage layer 20 is formed also on a side wall of the gate electrode 4. This damage layer 20 is readily oxidized.

Referring to FIG. 9, the silicon substrate 1 is heat-treated in a nitrogen atmosphere for forming an extremely thin SiN layer 18 on the surface of the gate electrode 4.

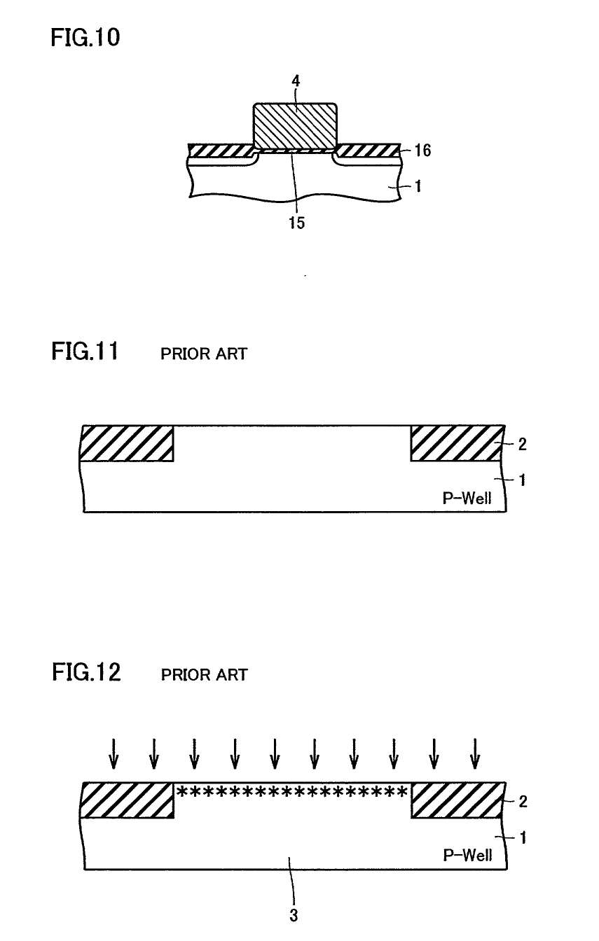

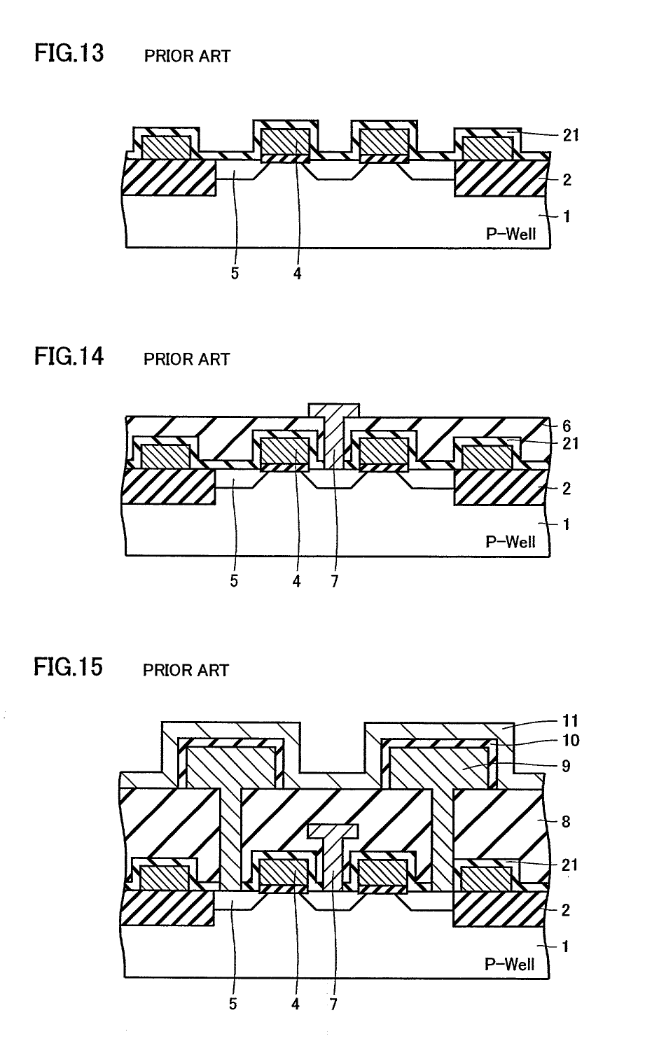

Referring to FIG. 10, the silicon substrate 1 is heat-treated in an oxidizing atmosphere. Thus, an additional oxide film 16 is formed and the shape abnormality 19 of the gate electrode 4 is corrected.

The damage layer 20 formed on the side wall of the gate electrode 4 is readily oxidized. When the damage layer 20 is oxidized, O₂ penetrates into the damage layer 20 to form an oxide film, thereby relaxing the shape of the projecting portion and removing a corner of an edge.

According to the present invention, as hereinabove described, a desired thickness of an oxide film can be obtained through short-time heat treatment, to cause no diffusion of impurities in a substrate. Further, a refresh property can be effectively improved without reducing a short margin of transistor characteristics.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of fabricating a semiconductor device comprising the steps of:
forming a gate electrode on a semiconductor substrate through a gate oxide film;
implanting impurity ions for forming source/drain regions on both sides of said gate electrode into the surface of said semiconductor substrate;
implanting inert ions into the surface of said semiconductor substrate;
heat-treating said semiconductor substrate in a nitrogen atmosphere for forming an SiN layer on the surface of said gate electrode; and
heat-treating said semiconductor substrate in an oxidizing atmosphere.

2. The method of fabricating a semiconductor device according to claim 1, wherein said inert ions contain Ar.

3. The method of fabricating a semiconductor device according to claim 1, wherein said inert ions are perpendicularly implanted into the surface of said semiconductor substrate.

4. The method of fabricating a semiconductor device according to claim 1, wherein said inert ions are obliquely implanted into the surface of said semiconductor substrate.

5. The method of fabricating a semiconductor device according to claim 1, wherein said heat-treating step in said nitrogen atmosphere is carried out by performing lamp annealing at a temperature of 900° C. to 1100° C.

6. The method of fabricating a semiconductor device according to claim 1, which is applied to fabrication of a dynamic random access memory.

7. A semiconductor device comprising:
a semiconductor substrate;
an oxide film formed on said semiconductor substrate; and
a gate electrode formed on said oxide film, wherein
first lower surfaces of said oxide film positioned on both sides of said gate electrode are located downward beyond a second lower surface of said oxide film positioned immediately under said gate electrode, and
said first lower surfaces and said second lower surface are connected with each other through step surfaces substantially perpendicularly extending downward from ends of said first lower surfaces.

8. The semiconductor device according to claim 7, further comprising an SiN layer covering the surface of said gate electrode.

9. The semiconductor device according to claim 7, including a dynamic random access memory.
